(19) United States
(12) Patent Application Publication
(10) Pub. No.: US 2004/0062103 A1
(43) Pub. Date: Apr. 1, 2004

(54) Memory circuit with a test mode for writing test data

(76) Inventor: Peter Beer, Tutzing (DE)

Correspondence Address: LERNER AND GREENBERG, P.A., POST OFFICE BOX 2480, HOLLYWOOD, FL, 33022-2480, US

(21) Appl. No.: 10/676,597

(22) Filed: Oct. 1, 2003

(30) Foreign Application Priority Data
Oct. 1, 2002 (DE) 102 45 712.3

(51) Int. Cl. G11C 29/00

(52) U.S. Cl. 365/200

(57) ABSTRACT

The invention relates to a memory circuit having a memory cell array. Memory cells in the memory cell array can be addressed via word lines and bit lines and can be written to via write amplifiers. Each of the write amplifiers is assigned to a plurality of bit lines. A datum can be written, in accordance with a write address, to a memory cell via the addressed bit line using the assigned write amplifier. An address decoding circuit is provided to simultaneously activate a plurality of the write amplifiers depending on a test mode signal so that the plurality of write amplifiers write the test datum present via the respectively assigned bit lines.

### BACKGROUND OF THE INVENTION

Field of the Invention

The invention relates to a memory circuit with a test mode for writing test data to a memory cell array in a highly parallel manner. The invention furthermore relates to a method for writing data to a memory circuit.

Semiconductor dynamic random access memories (DRAMs) have a memory cell array, in which memory cells are addressable via word lines and bit lines. The memory cells each include a storage capacitor connected to the respective bit line through the activation of a word line, so that the charge of the capacitor is added to the corresponding bit line. The bit lines are organized in pairs, and the activation of a word line results in only one storage capacitor being connected to one of the two bit lines of the bit line pair. This gives rise to a small charge difference between the bit lines of the bit line pair, which is amplified by a primary sense amplifier and fed to a secondary sense amplifier. In this case, a plurality of primary sense amplifiers form a group and are connected to a secondary read/write amplifier in each case via an assigned switching device. When writing a datum that is present at the secondary sense amplifier, one of the switching devices is activated, depending on the write address present, in order for the datum to be switched through to the corresponding bit line pair.

Semiconductor dynamic random access memories (DRAMs) have to be comprehensively tested in accordance with predetermined specifications after their production. To that end, test data are written to the memory cell array and are subsequently read out again. Afterward, the written-in and read-out data are compared with one another in order to ascertain a possible error. Some of the test sequences use very simple test patterns in which essentially the same datum is written to all the memory addresses of the memory cell array.

The writing is usually carried out successively, i.e. the memory addresses are successively addressed and written to. In order to accelerate the writing of data to the memory addresses, nowadays the test data for testing the DRAM are generated on the chip e.g. in a so-called BIST (Built-In Self-Test) circuit. It is also known, in the case of double data rate DRAMs, to shorten the write latency when writing test data. This is possible if the test data are known within the integrated circuit, so that it is no longer necessary to wait during the time in which the test data are normally read into the integrated circuit. All approaches that are intended to accelerate the writing of test data use the standard data path within the integrated circuit in order to write the test data to the respective memory address of the integrated circuit.

Furthermore, it is also known for all of the banks of a memory circuit to be written to simultaneously during testing in order thus to increase the writing of test data by a factor corresponding to the number of memory banks (factor of 4 in the case of 4 memory banks).

Despite all of the measures for increasing the writing of test data, the operation requires a considerable test time, and thus represents a non-negligible cost factor in testing memory chips.

### SUMMARY OF THE INVENTION

It is accordingly an object of the invention to provide a memory circuit and a method for writing data to the memory circuit, which overcome the above-mentioned disadvantages of the prior art apparatus and methods of this general type.

In particular, it is an object of the present invention to provide a memory circuit that can be tested faster. Furthermore, it is an object of the present invention to provide a method for testing such a memory circuit.

With the foregoing and other objects in view there is provided, in accordance with the invention, a memory circuit having a memory cell array. The memory cell array has memory cells which can be addressed via word lines and bit lines and can be written to via write amplifiers. Each of the write amplifiers is assigned to a plurality of bit lines. In accordance with a write address, a datum can be written to a memory cell via the addressed bit line by using the assigned write amplifier. The invention provides an address decoding circuit to simultaneously activate a plurality of write amplifiers depending on a test mode signal, so that the plurality of write amplifiers write the test datum present via the respectively assigned bit lines.

The memory circuit is thus configured in such a way as to simultaneously write test data to a plurality of memory addresses. This is expedient particularly in the case of test methods in which the same test datum is in each case intended to be written to the various memory addresses. The memory circuit makes use of the fact that a write amplifier is in each case available for a group of bit lines, and that it is possible for the write amplifiers to be operated independently of one another, in other words also jointly.

Consequently, it is possible to activate the write amplifiers simultaneously, so that a test datum present on the data bus is applied to a respectively assigned bit line determined by the write address.

Preferably, each of the write amplifiers can be connected to the assigned bit lines via a switching device in order to write the test datum from the activated write amplifiers to the addressed memory cell via the bit line addressed by the write address. The switching device usually likewise receives the write address in order to connect the bit line of the addressed memory cell to the write amplifier. Preferably, the switching device is in each case configured in such a way as to simultaneously connect the write amplifier to a plurality of assigned bit lines depending on the test mode signal.

With the foregoing and other objects in view there is also provided, in accordance with the invention, a method for writing data to a memory circuit. In this case, memory cells are addressed via word lines and bit lines and are written to via write amplifiers. Each of the write amplifiers is assigned to a plurality of bit lines. It is possible for a datum to be written, in accordance with a write address, to a memory cell via the addressed bit line by using the assigned write amplifier. For writing a test datum, a plurality of the write amplifiers are simultaneously activated depending on a test mode signal, so that the plurality of write amplifiers write the test datum present via the respectively assigned bit lines.

It may be provided that the write amplifiers are simultaneously connected in each case to a plurality of the assigned bit lines for writing the test datum. In this way, a test datum present on the data bus can also be written to a plurality of memory cells on bit lines assigned to a write amplifier.

Other features which are considered as characteristic for the invention are set forth in the appended claims.

Although the invention is illustrated and described herein as embodied in a memory circuit with a test mode for writing test data, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is schematic diagram showing a prior art memory cell array; and

FIG. 2 shows a detail from a preferred embodiment of an inventive memory circuit.

### DESCRIPTION OF THE PREFERRED EMBODIMENTS

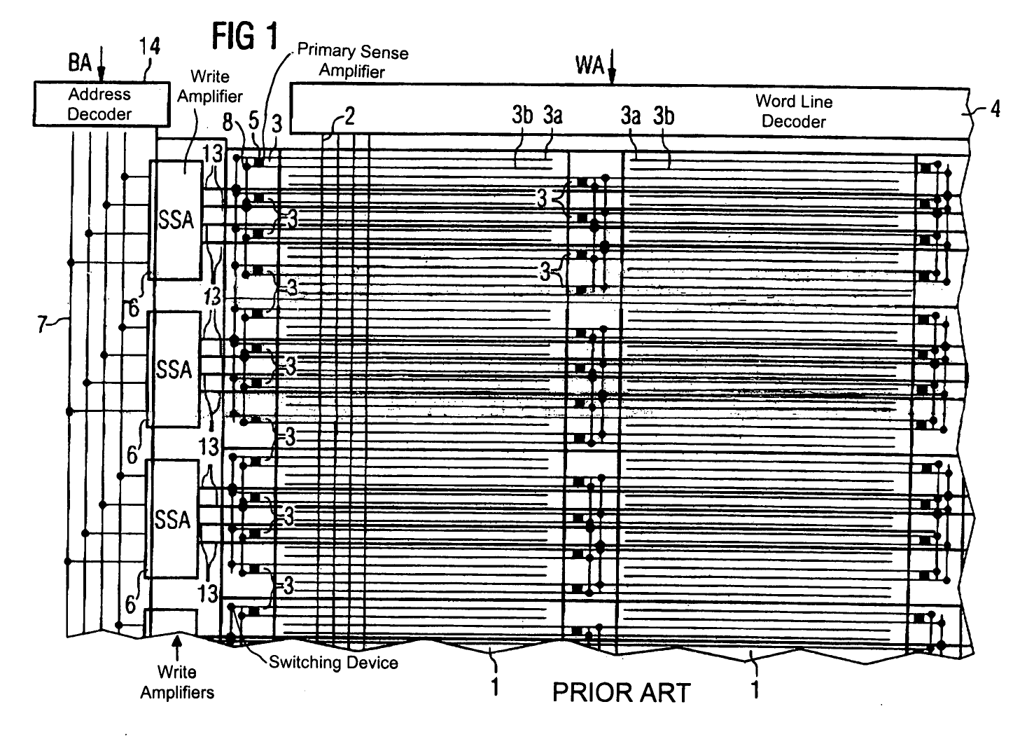

Referring now to the figures of the drawing in detail and first, particularly, to FIG. 1 thereof, there is shown a detail from a prior art memory circuit. The memory circuit has two memory cell arrays 1 that are arranged next to one another and that contain memory cells (not shown). The memory cells are situated at crossover points of word lines 2 and bit lines 3a, 3b and can be addressed via the latter. Two memory cells are illustrated by way of example by a filled-in circle at the crossover points of the first word line and first bit line. The word lines 2 are connected to a word line decoder 4 in order to activate one of the word lines 2 in accordance with a word line address WA provided to the word line decoder 4. The word line address WA represents part of a write address including the word line address WA and a bit line address BA. For the sake of better clarity, FIG. 1 illustrates only four word lines 2, but there are more than four word lines present per memory cell array 1, usually several thousand word lines. The bit lines 3a, 3b are organized in bit line pairs 3, and a primary sense amplifier 5 being arranged at one end thereof.

If a word line 2 is activated, then the storage capacitors of the memory cells are connected to a respective one of the bit lines 3a, 3b of a bit line pair 3. A small charge difference arises in each case on the bit lines 3a, 3b of a bit line pair 3, which is amplified by the primary sense amplifier 5.

The memory circuit has write amplifiers 6 each assigned to a group of eight bit line pairs 3. Each group of eight bit line pairs represents a y segment. The write amplifiers 6 write a datum provided by data lines 7 via the bit lines 3a, 3b of a bit line pair 3. To that end, the bit lines 3a, 3b are connected to the associated write amplifier 6 in each case via a switching device 8.

A datum is written to a memory address usually by a procedure in which first a write amplifier 6 is selected, under the control of an address decoder 14, by the bit line address BA made available and a datum is accepted from the data lines 7 into the selected write amplifier 6. The selected write amplifier 6 then makes the data to be written available on a master data line pair 13. From the master data line pair 13, the datum is applied via the switching device 8 to the connected bit line pair 3 with the bit lines 3a, 3b. The switching device 8 is likewise driven via the address decoder 14.

During normal operation of the memory circuit, only one switching device 8 is activated in order to connect the connected bit line to the write amplifier 6. The primary sense amplifier 5, situated at each bit line pair 3, is essentially not utilized for writing the data.

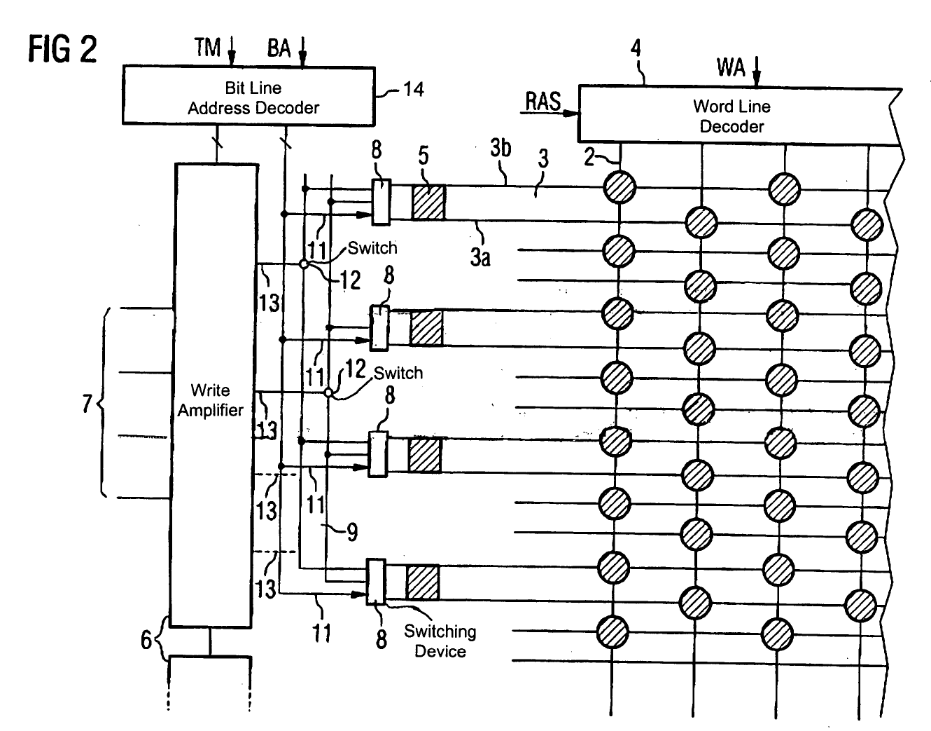

An inventive memory circuit is shown in an enlarged illustration in FIG. 2. The memory circuit according to FIG. 2 essentially corresponds to that shown in FIG. 1. Identical reference symbols relate to identical elements.

For reasons of clarity, FIG. 2 only illustrates a left-hand part of a y segment of a memory cell array 1 which is situated on the left-hand side of the memory cell array 1 of FIG. 1.

Each write amplifier 6 has, as an output, master data line pairs 13 on which the data to be written are output. In the example illustrated in FIG. 2, the write amplifier 6 has an upper and a lower master data line pair 13. The data are transmitted differentially on the master data line pairs. The upper master data line pair 13 is connected to a data line pair 9 via segment switches 12, so that the data to be written are also present differentially on the data line pair 9. The segment switch 12 is driven by more significant bits of the word line address and essentially selects the memory segment which has to be accessed. The driving of the segment switches 12 is usually effected by the word line decoder 4 and is not illustrated in FIG. 2 for reasons of clarity. The data line pair 9 is connected to the switching devices 8 for each bit line pair.

The lower master data line pair 13 is illustrated by broken lines and is connected via further segment switches to one or more further data line pairs of further memory cell arrays 1.

A comparable arrangement is provided at the right-hand edge of the memory cell array 1, i.e. every second bit line pair 3 is connected to a primary sense amplifier on the right-hand side of the memory cell array 1 which is connected to a further data line pair 9 in a switchable manner via further switching devices. The further data line pair can be connected to the lower master data line pair 13 via further segment switches 12.

In order to drive the addressed memory cell, the corresponding bit line or the corresponding bit line pair 3 has to be selected a bit line address BA. To that end, a bit line address decoder 14 is provided, which is illustrated as a block for reasons of clarity in FIG. 2. However, the bit line address decoder 14 may also be arranged in multiple fashion and near the respective switching device 8 that is driven via the bit line address decoder 14, or may be arranged in the vicinity of each write amplifier 6. Depending on the applied bit line address BA, the bit line address decoder 14 generates a column select signal CSL which is connected in each case to the switching device 8 to be selected, so that the switching device 8 can be switched depending on the column select signal. The select line 11 usually extends over a plurality of memory cell arrays 1, but, for reasons of clarity, is illustrated only as a connection between the bit line address decoder 10 and the switching device 8.

The write amplifier 6 is likewise selected by the bit line address BA by the bit line address decoder 14. The bit line address BA is preferably differentiated into a more significant part and a less significant part. While the column select lines 11 are selected with the more significant and the less significant part of the bit line address BA, write amplifiers 6 are selected only with the more significant part of the bit line addresses BA for writing data. If the bit line address decoder 14 is arranged in multiple fashion near the respective write amplifiers 6 to be driven, then a decoding circuit only for the more significant part of the bit line addresses BA is sufficient.

In a conventional memory circuit, the bit line address BA determines which of the column select lines 11 is activated. The activated column select signal CSL on the column select lines 11 activates the switching device 8 situated thereon. In this way, the datum present at the write amplifier 6 is switched through via the segment switch 12, the data line pair 9, and the addressed switching device 8 to the addressed bit line pair 3.

The bit line address decoder 14 is configured in such a way as to receive a test mode signal TM. An activated test mode signal TM has the effect that the decoding of the more significant y address bits—i.e. of the more significant part of the bit line address which is responsible for the selection of the y segment of the memory cell array—is masked, i.e. interrupted. In this case, the more significant y address bits are fixedly set to valid, so that all of the write amplifiers 6 of each segment are selected in the event of an activated test mode signal TM. The lower bit line address bits select the column select line 11 that specifies which of the switching devices 8 is to be activated.

If a datum is present on the data lines 7, these are amplified by the write amplifier 6 and output onto the master data line pair 13. The datum is applied to the addressed bit line pair 3 via the segment switches 12 and the switching devices 8. Since the less significant part of the bit line address BA is not masked, one of the switching devices 8 is selected in each y segment of the memory cell array 1, so that writing to an activated bit line 3 is effected in parallel in all the y segments.

The inventive circuit may be provided so that, during the testing of the integrated memory circuit, test data can be written in parallel to the memory cells of the memory cell array. The circuit previously represented has the advantage that only the bit line address decoder 14 has to be changed in order to enable the memory cells to be written to simultaneously. The additional outlay on circuitry is low even when, instead of an individual bit line address decoder 14, a plurality of bit line address decoders 14 are provided near the respective switching devices 8 or write amplifiers 6.

The masking, i.e. blocking of the selection of the y segments by the more significant parts of the bit line address bits can be modified by activating only some of the y segments. This is expedient when simultaneous writing would cause an excessively large loading on the voltage networks within the integrated memory circuit. For this reason, a plurality of test mode lines may be fed to the bit line address decoders 14. The described test mode for simultaneously writing data is carried out with a number of bit line address decoders 14 in the case of which the voltage supply networks within the integrated circuit are just not overloaded.

Depending on the test mode signal TM or depending on further test mode signals, the bit line address decoder 14 may also provide for more than one of the column select lines 11 to be activated per y segment, so that the data line pair 9 is simultaneously connected to more than one bit line pair 3.

I claim:

1. A memory circuit, comprising:
a memory cell array including a plurality of memory cells, said memory cell array including a plurality of word lines and a plurality of bit lines for addressing said plurality of memory cells;
a plurality of write amplifiers for writing to said plurality of memory cells, each one of said plurality of write amplifiers assigned to a group of said plurality of bit lines; and
an address decoding circuit for simultaneously activating a group of said plurality of write amplifiers, depending on a test mode signal, so that said group of said plurality of write amplifiers writes a test datum to a group of said plurality of memory cells via respectively assigned ones of said plurality of bit lines.

2. The memory circuit according to claim 1, further comprising:
a plurality of switching devices;
each one of said plurality of write amplifiers connected to assigned ones of said plurality of bit lines via a respective one of said plurality of switching devices in order to write the test datum from an activated one of said plurality of write amplifiers to an addressed memory cell via one of said plurality of bit lines addressed by a write address.

3. The memory circuit according to claim 2, wherein said address decoding circuit is configured to simultaneously connect one of said plurality of write amplifiers to assigned ones of said plurality of bit lines depending on the test mode signal.

4. A method for writing data to a memory circuit, which comprises:
providing a memory cell array including a plurality of memory cells;
providing the memory cell array with a plurality of word lines and a plurality of bit lines for addressing the plurality of memory cells;
providing a plurality of write amplifiers for writing to the plurality of memory cells, and assigning each one of the plurality of write amplifiers to a group of the plurality of bit lines;
simultaneously activating a group of said plurality of write amplifiers, depending on a test mode signal, so that the group of the plurality of write amplifiers writes a test datum to a group of the plurality of the memory cells via respectively assigned ones of the plurality of bit lines.

5. The method according to claim 4, which further comprises simultaneously connecting each amplifier in the group of the plurality of write amplifiers to assigned ones of the plurality of the bit lines for writing the test datum.
